(19) United States
(12) Patent Application Publication
(10) Pub. No.: US 2006/0224335 A1
(43) Pub. Date: Oct. 5, 2006

(54) Collecting interval data from a relative time battery powered automated meter reading devices

(75) Inventors: Andrew J. Borleske, Garner, NC (US); Robert T. Mason JR., Raleigh, NC (US)

Correspondence Address: WOODCOCK WASHBURN LLP, ONE LIBERTY PLACE, 46TH FLOOR, 1650 MARKET STREET, PHILADELPHIA, PA, 19103, US

(73) Assignee: Elster Electricity, LLC, Raleigh, NC (US)

(21) Appl. No.: 11/315,963

(22) Filed: Dec. 22, 2005

Related U.S. Application Data
(60) Provisional application No. 60/666,111, filed on Mar. 29, 2005.

(51) Int. Cl. G01R 21/00

(52) U.S. Cl. 702/62

(57) ABSTRACT

The invention provides a system and method for providing a time reference in utility meter network. The novel method includes transmitting a message from a meter to a receiving device (e.g., another meter, a collector, a data collection server), where the message includes an interval and a sequence number. The interval is converted to a time stamp, which is used to time-stamp the message in the receiving device. The novel method reads data from the meter and stores the data as a function of the sequence number.

### CROSS-REFERENCE TO RELATED APPLICATIONS

This application claims benefit to U.S. Provisional Application Ser. No. 60/666,111 filed Mar. 29, 2005. This disclosure is incorporated by reference in its entirety.

### FIELD OF THE INVENTION

The disclosed embodiments relate to wireless networks for collecting data, and more particularly, to systems and methods for collecting interval data on a fixed network Automated Meter Reading (AMR) system.

### BACKGROUND OF THE INVENTION

The collection of meter data from electrical energy, water, and gas meters has traditionally been performed by human meter-readers. The meter-reader travels to the meter location, which is frequently on a customer's premises, visually inspects the meter, and records the reading. Often, however, the meter-reader may be prevented from gaining access to the meter as a result of inclement weather or, where the meter is located within or on the customer's premises, due to an absentee customer. This methodology of meter data collection is labor intensive, prone to human error, and often results in stale and inflexible metering data.

Some meters have been enhanced to include a transceiver device for both transmitting metering data and receiving instructions. Often, a one-way battery-powered radio-frequency (RF) transmitter is used instead of a transceiver in order to reduce the meter's power consumption requirements. A person collecting meter data that is equipped with an appropriate radio receiver need only come into proximity with a meter to read the meter data and need not visually inspect the meter. Thus, a meter-reader may walk or drive by a meter location to take a meter reading. While this represents an improvement over visiting and visually inspecting each meter, it still requires human involvement in the process.

An automated means for collecting meter data involves a fixed wireless network. Devices such as, for example, repeaters and gateways are permanently affixed on rooftops and pole-tops and strategically positioned to receive data from enhanced meters fitted with radio-transmitters. Typically, these transmitters operate in the 902-928 MHz range and employ Frequency Hopping Spread Spectrum (FHSS) technology to spread the transmitted energy over a large portion of the available bandwidth. Data is transmitted from the meters to the repeaters and gateways and ultimately communicated to a central location. While fixed wireless networks greatly reduce human involvement in the process of meter reading, such systems require the installation and maintenance of a fixed network of repeaters, gateways, and servers.

With the increased sophistication of meter reading techniques has come the corresponding sophistication of billing techniques. For example, energy meters may be operated as either a “demand” meter or as a “time-of-use” (TOU) meter. TOU meters allow a power company to provide greater differentiation by which the energy is billed. Energy metered during peak hours will be billed differently than electrical energy billed during non-peak hours. Also, demand meters allow for a billing charge based on the maximum amount of power consumed in a given period of time (e.g. 15 min.) As a result, keeping track of time in the meter, both relative and absolute, has become more significant.

Yet, because of their use of battery-powered RF transmitters to conserve power consumption, it is often inefficient or impossible for the meter to receive time synchronization signals from external sources. Also, the service life of these meters can approach and even exceed 20 years. Therefore, it is impractical to set the time at the beginning of its life cycle during deployment, and expect the meter to keep accurate time throughout its service life. In addition, the technology required to keep time sufficiently accurate is prohibitively expensive.

Therefore, there is a need to provide efficient and inexpensive techniques for maintaining time characteristics in a meter.

### SUMMARY OF THE INVENTION

The invention provides a system and method for providing a time reference in utility meter network. The novel method includes transmitting a message from a meter to a receiving device (e.g., another meter, a collector, a data collection server), where the message includes an interval and a sequence number. The interval is converted to a time stamp, which is used to time-stamp the message in the receiving device. The novel method reads data from the meter and stores the data as a function of the sequence number.

The periodicity of the transmission of the message may be variable, while the periodicity of the receiving may be fixed. Also, the period for the meter reads may be greater than the period for the message transmissions. The method may further include assigning absolute time stamps to the time-stamped data. The novel method also may adjust the interval.

### BRIEF DESCRIPTION OF THE DRAWINGS

The foregoing summary, as well as the following detailed description of preferred embodiments, is better understood when read in conjunction with the appended drawings. For the purpose of illustrating the invention, there is shown in the drawings exemplary constructions of the invention; however, the invention is not limited to the specific methods and instrumentalities disclosed. In the drawings:

FIG. 1 is a diagram of a wireless system for collecting data from remote devices;

FIG. 2 expands upon the diagram of FIG. 1 and illustrates a system in which the present invention is embodied; and

FIG. 3 provides a flow diagram of a method for providing a time reference in utility meter network, according to the invention.

### DETAILED DESCRIPTION OF ILLUSTRATIVE EMBODIMENTS

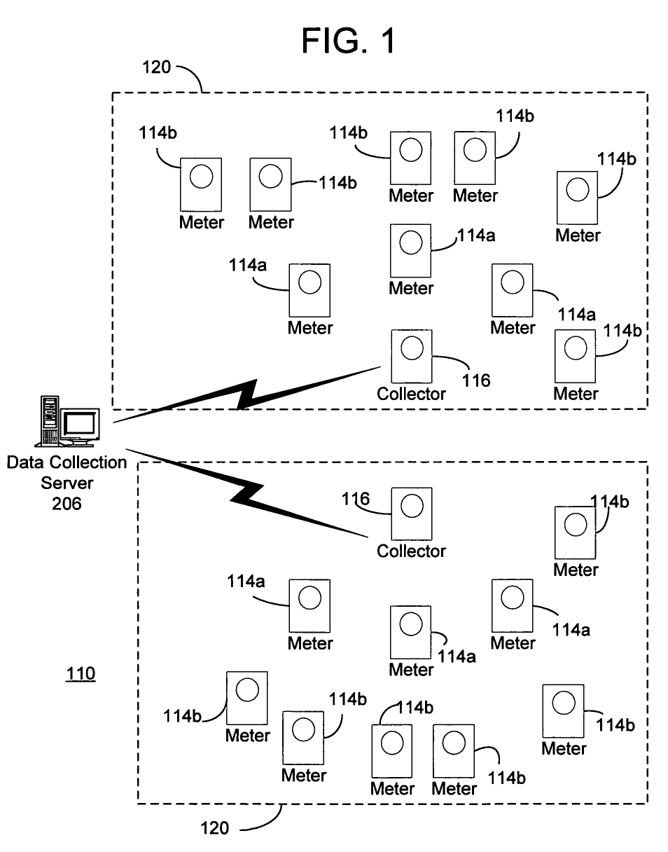

Exemplary systems and methods for gathering meter data are described below with reference to FIGS. 1-3. It will be appreciated by those of ordinary skill in the art that the description given herein with respect to those figures is for exemplary purposes only and is not intended in any way to limit the scope of potential embodiments.

Generally, a plurality of meter devices, which operate to track usage of a service or commodity such as, for example, electricity, water, and gas, may be operable to wirelessly communicate with each other, and/or to communicate with one another via a wireline network. A collector may be operable to automatically identify and register meters for communication with the collector. When a meter is installed, the meter becomes registered with the collector that can provide a communication path to the meter. The collectors may receive and compile metering data from a plurality of meter devices via wireless communications. Also, a communications server communicates with the collectors to retrieve the compiled meter data.

FIG. 1 provides a diagram of an exemplary metering system 110. System 110 comprises a plurality of meters 114, which are operable to sense and record usage of a service or commodity such as, for example, electricity, water, or gas. Meters 114 may be located at customer premises such as, for example, a home or place of business. Meters 114 may comprise an antenna and may be operable to transmit data, including service usage data, wirelessly or via wired connections. Meters 114 may be further operable to receive data wirelessly as well. In an illustrative embodiment, meters 114 may be, for example, electrical meters manufactured by Elster Electricity, LLC.

System 110 may further comprise collectors 116. Collectors 116 also may be meters operable to detect and record usage of a service or commodity such as, for example, electricity, water, or gas. Collectors 116 may comprise an antenna and may be operable to send and receive data wirelessly. In particular, collectors 116 may be operable to send data to and receive data from meters 114. In an illustrative embodiment, meters 114 and/or collectors 116 may be, for example, an electrical meter manufactured by Elster Electricity, LLC.

A collector 116 and the meters 114 for which it is configured to receive meter data define a subnet/LAN 120 of system 110. In the context of networking, meters 114 and collectors 116 may be considered as nodes in the subnet 120. For each subnet/LAN 120, data may be collected at collector 116 and periodically transmitted to a data collection server 206. The data collection server 206 may store the data for analysis and preparation of bills, for example, among others. The data collection server 206 may be a specially programmed general purpose computing system and may communicate with collectors 116 wirelessly or via a wireline connection such as, for example, a dial-up telephone connection or fixed wire network.

Generally, collector 116 and meters 114 may communicate with and among one another using any one of several robust wireless techniques such as, for example, frequency hopping spread spectrum (FHSS) and direct sequence spread spectrum (DSSS). As illustrated, meters 114a may be referred to as “first level” meters that communicate with collector 116, and meters 114b may be referred to as “higher level” meters that communicate with other meters in the network and that forward information to the collector 116.

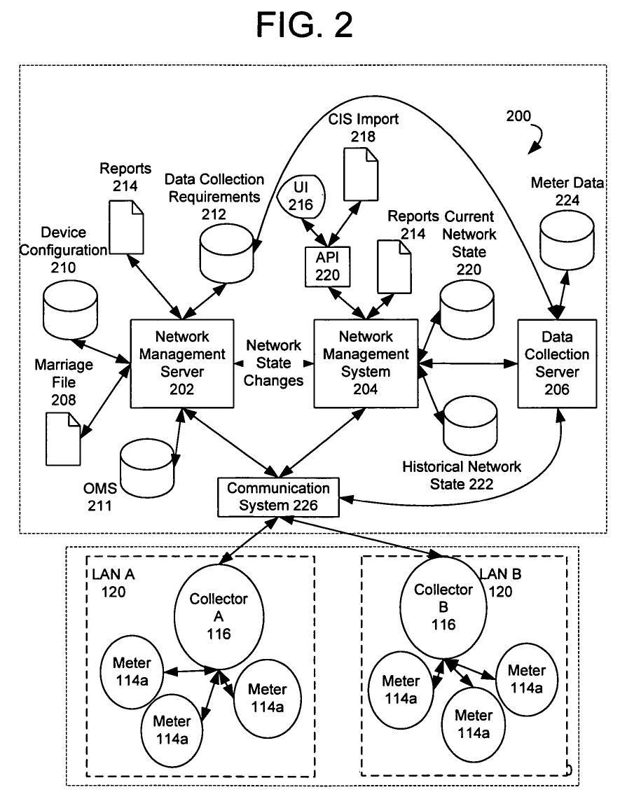

Referring now to FIG. 2, there is illustrated a system 200. The system 200 may include a network management server 202, a network management system (NMS) 204 and a data collection server 206 that together manage one or more subnets/LANs 120 and their constituent nodes. The NMS 204 may track changes in the network state, such as new nodes registering/unregistering with the system 200, node communication paths changing, etc. This information may be collected for each subnet/LAN 120 and may be detected and forwarded to the network management server 202 and data collection server 206.

Communication between nodes and the system 200 may be accomplished using a LAN identification, however customers also may query and communicate with nodes using their own identifier. To this end, a marriage file 208 may be used to correlate a customer serial number, a manufacturer serial number and LAN identification for each node (e.g., meters 114a and collectors 116) in the subnet/LAN 120. A device configuration database 210 may store configuration information regarding the nodes. For example, in the metering system 110, the device configuration database may include data regarding time of use (TOU) switchpoints, etc. for the meters 114a and collectors 116 communicating to the system 200. A data collection requirements database 212 may contain information regarding the data to be collected on a per node basis. For example, a user may specify that metering data such as load profile, demand, TOU, etc. is to be collected from particular meter(s) 114a. Reports 214 containing information on the network configuration may be automatically generated or in accordance with a user request.

A network management system (NMS) 204 maintains a database describing the current state of the global fixed network system (current network state 220) and a database describing the historical state of the system (historical network state 222). The current network state 220 may contain data regarding current meter to collector assignments, etc. for each subnet/LAN 120. The historical network state 222 may be a database from which the state of the network at a particular point in the past can be reconstructed. The NMS 204 may be responsible for, among other things, providing reports 214 about the state of the network. The NMS 204 may be accessed via an API 220 that is exposed to a user interface 216 and a Customer Information System (CIS) 218. Other external interfaces may be implemented as well. In addition, the data collection requirements stored in the database 212 may be set via the user interface 216 or CIS 218.

The data collection server 206 collects data from the nodes (e.g., collectors 116) and stores the data in a database 224. The data may include metering information, such as energy consumption and may be used for billing purposes, etc. by a utility provider.

The network management server 202, network management system 204 and data collection server 206 may communicate with the nodes in each subnet/LAN 120 via a communication system 226. The communication system 226 may be a Frequency Hopping Spread Spectrum radio network, a mesh network, a Wi-Fi (802.11) network, a Wi-Max (802.16) network, a land line (POTS) network, etc., or any combination of the above and enables the system 200 to communicate with the metering system 110.

In a system such as that shown in FIGS. 1 and 2, there are instances when the meter's internal time clock drifts. Devices with receivers have means to receive messages to update the time and to maintain the real time within the device. However, transmit only devices, for example, may not have a mechanism that allows the time to be synchronized to the real time. In addition, devices that are capable of receiving and transmitting, and thus receiving time updates, may require backup or validation of those received time updates. The disclosed embodiments apply to both types of systems, as well as others.

An embodiment of the invention may provide techniques for maintaining a relative time in a device, like a meter 114, for example. The relative time may then be mapped to an absolute time in a receiving device, for example the meter 114 and/or the collector 116.

A module, for example a communication module, in a meter or other type of the automated meter reading (AMR) device may maintain a relative time clock. The relative time clock may be a timer that it internal to the meter, and may operate independently of an absolute time input. The relative time clock in the meter or AMR device may allow the AMR device to read the meter to which it is attached and may allow the meter to transmit its data, both of which may be scheduled on a periodic basis.

A meter read may be, for example, a snapshot of the current consumption value of the meter. The frequency with which the meter read is conducted may be referred to as a read interval. The read interval determines an interval length of interval data. The meter read can be accomplished by an accumulation of pulses or an absolute value read from the meter device. The read meter data may be stored in a memory, register or other data storing mechanism in the meter device.

After reading the meter consumption value, the communication module in the meter or AMR device may compute the interval data by calculating the difference between the last consumption value read and the previous consumption value read. The AMR device also may apply a preset divisor in order to ensure the interval fits in the allotted memory space. The data that is read also may be assigned a sequence number and stored in a log.

It should be appreciated that the interval at which the meter 114 may record the data and the interval at which the meter 114 or communication module transmits that data up to the next item in the network, for example the collector 116 or another meter, may be different. For example, the communication module in the meter 114 may remain in a low power or power off state and “wake up” every hour, for example, to read the meter and to record the interval data, even though the meter 114 may transmit data every four hours. In fact, because the power consumed by the meter 114 in transmitting data often is greater than the power consumed from simply recording the meter data, it may be desirable and more efficient to increase the period between transmissions from the communication module to a number greater than the period between data reads. Therefore, the meter read period may either be a time period over which pulses are accumulated or the frequency at which the communications module “wakes up” and reads the meter register. Also, it should be appreciated that the meter read period may be set at a value that includes other considerations, like power usage, battery availability, etc.

It should also be appreciated that the periodicity of the meter reads may be decreased (e.g., 15 minute intervals) in order to provide a finer time resolution. Also, it may be desirable to increase the meter module's memory and radio frequency (RF) message payload such that the meter 114 may store and transmit more than 24 intervals of data. The number of intervals and time of the intervals are provided merely as an example and are not meant to be exclusive. The unlimited design values that contemplate tradeoffs in power, memory, and processing speed, just to name a few, are well within the scope of the described embodiments.

In operation, the communication module in the meter 114 may transmit a message to another device or devices capable of receiving the message, for example, a collector 116 and/or another meter. Although the collector 116 may be described as being the receiving device, it should be appreciated that any of the other network elements capable of receiving may receive the message. The message may include all or a portion of the recorded interval log, as well as the sequence number of the most recent entry.

Upon being received, the message may be time-stamped or given a time value by the receiving device. For example, where the transmission interval is designated as fifteen minutes, the message and interval data may be time-stamped to a resolution of fifteen minutes. The receiving device may then forwards the message, with the added time-stamp, to the collecting device 116, for example. It should be appreciated that the collector 116 and the receiving device also may be utility meters. Where the entire interval data log is sent with every transmission (e.g., 24 intervals), the collecting device 116 may determine which intervals it has not yet stored (e.g., based on the sequence number of the received transmission), and may add the intervals to its log. The collecting device 116 may then convert the interval number to an absolute timestamp or time value, and may associate it with the newest interval.

The collecting device 116 therefore may aggregate the periodic transmissions from the meter 114. As such, the collecting device 116 may store multiple days of load profile data for each meter 114.

The data collection server 206 may then read the collector 116. In one embodiment, the data collection server 206 may read the collector 116 by evaluating the sequence number to read data it has not yet received. The data collection server 206 may have access to information not contained in the message transmitted from the meter 114 via a “marriage file” provided by the collecting device 116. For example, the data collection server 206 may use a divisor used by the meter 114 to convert the received interval data to engineering units, thereby may store and reporting the interval data in human understandable units.

In addition to periodic transmissions of data from meter 114, the transmit period may be programmed to vary randomly. Randomly transmitting the data may prevent two proximate meters from undesirably transmitting at the same time to the same collector, such that the collector 116 and/or the meter with receiver 114 can receive transmissions from two different devices, but not at the same time. Therefore, allowing the meters to randomly transmit their data may increase the probability that a greater number of transmitted messages may be received and stored by the collector 116, and/or received and stored by the meter 114 such that it can be forwarded to the collector 116. The degree of uncertainty may therefore increases the length of the interval (e.g., 1 hour). While the relaying device, for example the collector 116, stamps the message with the 15-minute interval, for example, the reading device (e.g., data collection server 206) may assign the message to the nearest interval boundary prior to the stamped time.

It should be appreciated that any of meters 114 may be a two-way device capable of receiving and transmitting data and/or a one-way device capable of receiving data. Also, it should be appreciated that any of collectors 116 also may be either two-way or one-way devices. Furthermore, the scope of the contemplated embodiments are not limited to the transmit/receive capabilities of any of the devices, but instead contemplate devices of any communication capability.

Once the data collection server 206 establishes the time of its first read, it may use that boundary for each subsequent read. However, because the time of the meter 114 may drift over time, the data collection server 206 may act to verify that the same boundary definition continues to be valid with each read. Once the time has drifted enough for the current boundary to be invalid, the data collection server 206 may act to correct the interval time-stamp for the new data and resynchronize to the new boundary. These changes may be marked with an event flag to indicate to the end user of the data that an adjustment was made.

Often, it may be necessary to allow for the collection of interval data at higher resolution intervals. For example, when a customer service issue requires finer resolution of data in order to facilitate troubleshooting of a problem. However, because the collector 116 may have a defined amount of memory that can be allocated to collecting interval data from the meter 114 it may be necessary to consider techniques other than the addition of memory to the collector 116.

For example, the system 200 may be configured to decrease the number of meters 114 for which the particular collector 116 stores interval data. This may be accomplished by using the data collection server 206 to dynamically configure the collector 116 to collect interval data for a subset of the originally planned meters. For example, the collector 116 may store interval data for certain identified meters 114. For the other meters not separately identified, the collector 116 may be made to store a smaller portion of the typical data (e.g., total consumption and status information). Therefore, this technique allows the system 200 to more efficiently optimize the memory available in the collector 116 by saving the expense of installing additional collectors into the system 200, or having to install additional memory on a given collector.

As part of the typical operation of a fixed network system as described above, it should be appreciated that data from a single meter 114a may be received by multiple collectors 116. After identifying the user's subset of meters 114, the data collection server 206 may group the meters into those applicable to a given collector 116. Moreover, the data collection server 206 may instruct multiple collectors to store interval data for the same meter 114a. In fact, the mesh network architecture and path diversity provided by the meters that are capable of receiving the transmit message from other meters allow for a robust data collection system. The data collection server 206 can receive data from the meter 114a through multiple collectors. As discussed, the data collection server 206 may determine if the data it receives from the collector 116 is new or old data, such that the new information is stored data, and the old data is perhaps discarded.

In addition to time-stamping, a method may be available for date-stamping by the system 200 for devices that otherwise typically do not track the date. For example, both the transmit-only meters, transmit and receive meters, and certain collectors that receive the transmit message may not contain date information. Other collectors capable of date-stamping may use the date and time that it maintains internally, as well as the time stamp provided by the transmit and receive meters and other collectors.

Although certainly not exclusive of all possible embodiments, the following example is provided to help further understand the concepts discussed.

In the example embodiment, the relative clock of a communication module for a water meter may have hour boundaries that are set at 18 minutes past hour absolute time. The communication module also may have meter reads scheduled at 0:18, 1:18, 2:18, and 3:18, and the meter is set to transmit a message at 3:18. The sequence numbers for each of those reads may be designated as 124, 125, 126, and 127, respectively. In the 3:18 transmission, the time module transmits interval data from 4:18 the previous day to the current interval at 3:18 (e.g., 24 1-hour intervals).

A receiving meter and/or collector may stamp the transmit message with the interval number 13, because 3:15 to 3:30 it is the thirteenth, fifteen minute interval. In the example, the data last read by the collector for the water meter had a sequence number of 119. The collector reads the data from the receiving meter, stores the new consumption and status information, and adds the most recent eight intervals to the collector log (e.g., intervals 120-127). The collector also may update the sequence number for the water meter to 127. The remaining sixteen intervals of data are duplicate information (i.e., already received and stored by the collector), and therefore may be discarded. The collector may time-stamp the most recent interval (i.e., sequence number 127) with a time of 3:15 and may add the current date to the timestamp.

In the example, the last time the data collection server read the collector, it read interval data up to sequence number 103. At the next read, the data collection server determines that there are twenty-four new intervals. Therefore, the data collection server may read the new data and may assign timestamps starting with time stored in the data collection server from the previous read of interval number 103. The data collection server also may verify that the new twenty-four intervals are still in correct time periods, and therefore no adjustment to the time is required.

Assuming, in the example, that the battery powered module had been set up for a varying transmit period, the data may have been the same, but the transmit may have occurred at 4:16 (i.e., it could have occurred at any time between 3:18 to 4:18). The receiving meter would stamp the message with the interval number 17, because 4:15 to 4:30 is the seventeenth, 15 minute interval. The collector would timestamp it as 4:15. When the data collection server reads the data, it calculates a date and time for the start of each interval based on the existing (i.e., previous retrieved and stored) data. The data collection server then adjusts the interval date and time stamps if the timestamps received from the collector were more than one hour different than expected (i.e., the level of uncertainty, equal to one interval length).

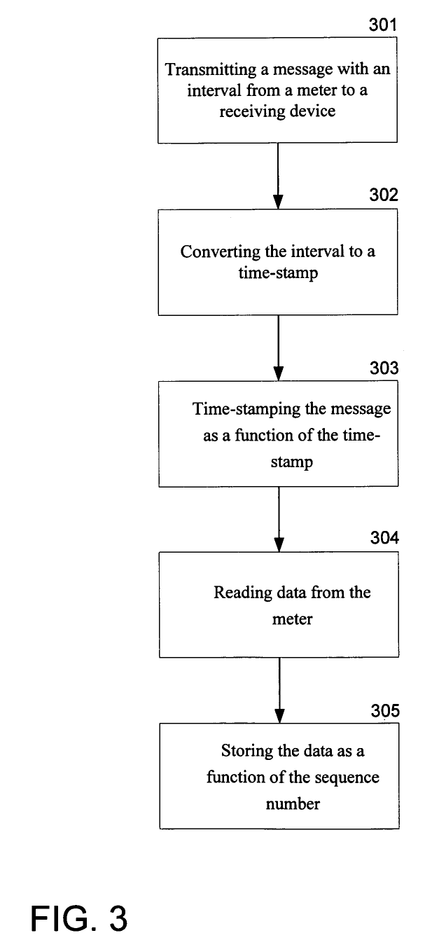

FIG. 3 provides a flow diagram of a method for providing a time reference in utility meter network, according to the invention. As shown in FIG. 3, in step 301, a message is transmitted from a meter to a receiving device. The message may include an interval and a sequence number. In step 302, the interval is converted to a time-stamp and in step 303 the message is time-stamped as a function of the time-stamp in the receiving device. In step 304, data is read from the meter and in step 305 data is stored as a function of the sequence number.

It should be appreciated that the embodiments contemplate the message being time-stamped by the meter itself, instead of by the receiving device. In this instance, the meter may act as a receiving device and/or a collector device and apply a date and time-stamp to the message, based on the sequence number. In fact, it should be appreciated that the embodiments contemplate other communication paths not described, but still within the scope of the described embodiments.

It is to be understood that the foregoing illustrative embodiments have been provided merely for the purpose of explanation and are in no way to be construed as limiting of the invention. Words used herein are words of description and illustration, rather than words of limitation. In addition, the advantages and objectives described herein may not be realized by each and every embodiment practicing the present invention. Further, although the invention has been described herein with reference to particular structure, materials and/or embodiments, the invention is not intended to be limited to the particulars disclosed herein. Rather, the invention extends to all functionally equivalent structures, methods and uses, such as are within the scope of the appended claims.

For example, although a great deal of the discussion was based on the use of certain devices and communication paths, it should be appreciated that the contemplated embodiments include the use of any devices, communication paths and techniques. Moreover, although device configurations have been described herein, it should be appreciated that the devices are provided merely to provide an understanding of the many techniques contemplated by the embodiments. Those skilled in the art, having the benefit of the teachings of this specification, may affect numerous modifications thereto and changes may be made without departing from the scope and spirit of the invention.

What is claimed is:

1. A method for communicating in a utility meter network, comprising:
establishing a relative time frame in a utility meter;
receiving data from a utility meter to a receiving device based on a relative time of the utility meter;
applying a time value to the data based on an absolute time; and
storing the data along with the time value.

2. The method of claim 1, wherein the receiving device is at least one of the following:
another meter, a collector, a data collection server.

3. The method of claim 1, further comprising determining the storing based on the receiving device.

4. The method of claim 1, wherein the period of transmitting is variable.

5. The method of claim 1, wherein the receiving is accomplished on a fixed period.

6. The method of claim 1, wherein the receiving is conducted on a mesh radio-frequency network.

7. The method of claim 1, wherein the data comprises an interval and a sequence number.

8. The method of claim 7, further comprising adjusting the interval.

9. The method of claim 7, further comprising converting the interval to the time value.

10. The method of claim 7, further comprising storing the data as a function of the sequence number.

11. A utility meter network, comprising:
a utility meter; and
a first device in communication with the utility meter, wherein the utility meter transmits data to the first device, and wherein the first device assigns a time to the data.

12. The network of claim 11, further comprising a communication module in communication with the utility meter.

13. The network of claim 12, wherein the communication module is located within the utility meter.

14. The network of claim 13, wherein the communication module transmits the data to the first device.

15. The network of claim 13, wherein the communication module transmits remains in one of the following states until the data is transmitted: a low power state and an off state.

16. The network of claim 11, wherein the utility meter is a transmit-only device.

17. The network of claim 11, wherein the utility meter is a transmitter/receiver device.

18. The network of claim 11, wherein the utility meter is powered by a battery.

19. The network of claim 11, wherein the utility meter periodically transmits data to the first device.

20. The network of claim 19, wherein the period of transmission is based on a time relative to the utility meter.

21. The network of claim 19, wherein the period of transmission is based on a time relative to the utility meter.

22. The network of claim 11, further comprising a data server in communication with the first device.

23. The network of claim 22, wherein the utility meter transmits data to the first device at a rate less than a rate at which the first device transmits data to the data server.

24. The network of claim 11, wherein the utility meter is at least one of the following: an electricity meter, a water meter, a gas meter.

25. The network of claim 11, wherein the first device assigns to the time to the data based on an absolute time value.

26. The network of claim 11, wherein the first device creates a sequence of time-stamps.

27. The network of claim 11, wherein the first device is a collector.

28. The network of claim 11, wherein the first device is another utility meter.

29. The network of claim 11, wherein the data comprises an interval and a sequence number.
